(19) United States
(12) Patent Application Publication
(10) Pub. No.: US 2026/0121623 A1
(43) Pub. Date: Apr. 30, 2026

(54) LATCH CIRCUIT, DYNAMIC LATCH, DYNAMIC D FLIP-FLOP, AND RELATED APPARATUSES

(71) Applicant: SHENZHEN MICROBT ELECTRONICS TECHNOLOGY CO., LTD., SHENZHEN, GUANGDONG (CN)

(72) Inventors: Wenbo TIAN, SHENZHEN, GUANGDONG (CN); Chuan GONG, SHENZHEN, GUANGDONG (CN); Haifeng GUO, SHENZHEN, GUANGDONG (CN)

(73) Assignee: SHENZHEN MICROBT ELECTRONICS TECHNOLOGY CO., LTD., SHENZHEN, GUANGDONG (CN)

(21) Appl. No.: 19/151,942

(22) PCT Filed: Apr. 11, 2025
(86) PCT No.: PCT/CN2025/088458

§ 371 Date: Jul. 29, 2025

(30) Foreign Application Priority Data
Jun. 13, 2024 (CN) 202410758098.0

(51) Int. Cl. H03K 3/356; H03K 3/037

(52) U.S. Cl. CPC H03K 3/356104; H03K 3/037

(57) ABSTRACT

The present disclosure provides a latch circuit, a dynamic latch, a dynamic D flip-flop, and related apparatuses. The latch circuit includes: first and second transistor groups of a first conduction type and third and fourth transistor groups of a second conduction type that are sequentially connected in series between a power supply and ground. A node between the second and third transistor groups is connected to an output end. A control end of one of the first and second transistor groups and a control end of one of the third and fourth transistor groups are jointly connected to an input end. The other of the first and second transistor groups receives a first clock signal. The other of the third and fourth transistor groups receives an inverted second clock signal. At least one of the first to fourth transistor groups includes a plurality of transistors connected in series.

### CROSS-REFERENCE TO RELATED APPLICATIONS

This application is based on and claims priority to Chinese Patent Application No. 202410758098.0 filed on Jun. 13, 2024, the disclosure of which is incorporated herein by reference in its entirety.

### TECHNICAL FIELD

The present disclosure generally relates to the field of integrated circuit technologies, and more specifically, to a latch circuit, a dynamic latch, a dynamic D flip-flop, a register, a processor, and a computing apparatus.

### BACKGROUND

As high-performance computing has been widely used in the fields of exploration, climate change, transportation, artificial intelligence, and the like, a requirement for a computing chip on power consumption, computing speed, and area (cost) is getting higher. The computing chip needs to use a latch to perform data latching, and a higher computational load requires the computing chip to use more latches. Therefore, performance of the latch directly affects performance of the computing chip.

### SUMMARY

According to a first aspect of the present disclosure, a latch circuit is provided. The latch circuit includes: an input end; an output end; and a first transistor group of a first conduction type, a second transistor group of the first conduction type, a third transistor group of a second conduction type different from the first conduction type, and a fourth transistor group of the second conduction type that are sequentially connected in series between a power supply and ground. A node between the second transistor group and the third transistor group is connected to the output end. A control end of one of the first transistor group and the second transistor group and a control end of one of the third transistor group and the fourth transistor group are jointly connected to the input end. A control end of the other of the first transistor group and the second transistor group is configured to receive a first clock signal. A control end of the other of the third transistor group and the fourth transistor group is configured to receive a second clock signal that is inverted with respect to the first clock signal. The first conduction type is configured such that a transistor is turned on when a control end of the transistor is at a low level. The second conduction type is configured such that a transistor is turned on when a control end of the transistor is at a high level. At least one of the first to fourth transistor groups includes a plurality of transistors connected in series.

According to a second aspect of the present disclosure, a dynamic latch is provided. The dynamic latch includes: a data input end configured to receive a data signal; a data output end configured to output the data signal; a clock control end configured to receive a clock signal; and a latch unit and an inverting drive unit that are sequentially connected in series between the data input end and the data output end. The latch unit is configured to latch or transmit the data signal from the data input end under control of the clock signal. The inverting drive unit is configured to invert and transmit the data signal from the latch unit. The latch unit includes the latch circuit according to the first aspect of the present disclosure.

According to a third aspect of the present disclosure, a dynamic D flip-flop is provided. The dynamic D flip-flop includes: a data input end configured to receive a data signal; a data output end configured to output the data signal; a clock control end configured to receive a clock signal; and a first latch unit, a second latch unit, and an inverting drive unit that are sequentially connected in series between the data input end and the data output end. The first latch unit is configured to latch or transmit the data signal from the data input end under control of the clock signal. The second latch unit is configured to latch or transmit the data signal from the first latch unit under control of the clock signal. The inverting drive unit is configured to invert and transmit the data signal from the second latch unit.

In some embodiments, the first latch unit includes the latch circuit according to the first aspect of the present disclosure.

In some embodiments, the second latch unit includes the latch circuit according to the first aspect of the present disclosure.

According to a fourth aspect of the present disclosure, a register is provided. The register includes: a plurality of data input ends configured to receive data signals; a plurality of data output ends configured to output the data signals; a clock control end configured to receive a clock signal; a clock buffer configured to buffer the clock signal received by the clock control end and provide the clock signal to a plurality of register units; and the plurality of register units connected in parallel between the plurality of data input ends and the plurality of data output ends and configured to perform at least one of data writing or data reading under control of the clock signal. The register unit of the plurality of register units is the dynamic latch according to the second aspect of the present disclosure, or the dynamic D flip-flop according to the third aspect of the present disclosure.

According to a fifth aspect of the present disclosure, a processor is provided. The processor includes: the dynamic latch according to the second aspect of the present disclosure; or the dynamic D flip-flop according to the third aspect of the present disclosure; or the register according to the fourth aspect of the present disclosure.

According to a sixth aspect of the present disclosure, a computing apparatus is provided. The computing apparatus includes the processor according to the fifth aspect of the present disclosure.

Further features of the present disclosure and advantageous thereof will become apparent from the following detailed description of illustrative embodiments of the present disclosure with reference to the accompanying drawings.

### BRIEF DESCRIPTION OF THE DRAWINGS

The accompanying drawings, which constitute a part of the specification, describe the embodiments of the present disclosure and, along with the specification, serve to illustrate principles of the present disclosure. The present disclosure can be more clearly understood from the following detailed description with reference to the accompany drawings, in which:

FIG. 1 is a schematic diagram showing a circuit of a dynamic latch according to a comparative example of the present disclosure;

FIG. 2 shows a dynamic latch according to some embodiments of the present disclosure;

FIG. 3 shows a clock buffer according to some embodiments of the present disclosure;

FIG. 4 shows a dynamic latch and a clock circuit associated with the dynamic latch according to some embodiments of the present disclosure;

FIG. 5 to FIG. 18 are schematic diagrams each showing a circuit of a dynamic latch according to some embodiments of the present disclosure;

FIG. 19 shows a dynamic D flip-flop according to some embodiments of the present disclosure;

FIG. 20 to FIG. 25 are schematic diagrams each showing a circuit of a dynamic D flip-flop according to some embodiments of the present disclosure;

FIG. 26 shows a register according to some embodiments of the present disclosure;

FIG. 27 is an example time sequence diagram for the circuit of the dynamic latch shown in FIG. 7; and

FIG. 28 is an example time sequence diagram for the circuit of the dynamic latch shown in FIG. 10.

It is noted that in the embodiments described below, sometimes the same reference numerals are used in common between different drawings to represent the same parts or parts with the same functions, and their repeated descriptions are omitted. In the specification, similar numbers and letters are used to represent similar items, so once an item is defined in one drawing, it does not need to be further discussed in other drawings unless stated otherwise.

For ease of understanding, the positions, dimensions, ranges, etc. of structures shown in the drawings and the like may not represent the actual positions, dimensions, ranges, etc. Therefore, the present disclosure is not limited to the positions, dimensions, ranges, etc. disclosed in the drawings and the like. In addition, the drawings need not be drawn to scale, and some features may be enlarged to illustrate the details of specific components.

### DETAILED DESCRIPTION

Various illustrative embodiments of the present disclosure will be described in detail below with reference to the accompanying drawings. It should be noted that unless otherwise specifically stated, the relative arrangement of components and steps, numerical expressions and numerical values set forth in these embodiments do not limit the scope of the present disclosure.

The following description of at least one illustrative embodiment is in fact merely illustrative and is in no way intended to limit the present disclosure and its application or use. That is, the structures and methods herein are shown as examples to illustrate different embodiments of the structures and methods in the present disclosure. However, those skilled in the art will appreciate that they merely describe illustrative ways of the present disclosure that can be implemented, rather than exhaustive ways. In addition, the drawings need not be drawn to scale, and some features may be enlarged to illustrate the details of specific components.

In addition, technologies, methods, and devices known to ordinary technicians in the relevant art may not be discussed in detail, but where appropriate, the technologies, methods, and devices should be considered as a part of the specification.

In all examples shown and discussed herein, any specific values should be interpreted as merely illustrative and not as limiting. Therefore, other examples of the illustrative embodiments may have different values.

It should be understood that, although the accompanying drawings in this specification are mainly described by using a metal-oxide-semiconductor (MOS) transistor as an example, the present disclosure is not limited thereto, and any other suitable transistor may alternatively be used, including but not limited to, a bipolar junction transistor (BJT) and the like.

It should be further understood that, in this specification, a control end of a transistor may refer to a terminal used to control flow of a current and an on/off state of the transistor, and transmission ends of the transistor may refer to terminals through which a current or a signal is inputted to and outputted from the transistor. For example, specifically, for a MOS transistor, the control end is a gate, and the transmission ends are a source and a drain. For a BJT, the control end is a base, and the transmission ends are an emitter and a collector.

It should be further understood that, in this specification, a first conduction type may be configured such that a transistor is turned on when a control end of the transistor is at a low level, and a second conduction type may be configured such that a transistor is turned on when a control end of the transistor is at a high level. For example, specifically, for a MOS transistor, the first conduction type is P-type, and the second conduction type is N-type. For a BJT, the first conduction type is PNP-type, and the second conduction type is NPN-type.

It should be further understood that, in this specification, a power supply and ground are relative concepts, which exist in relation to each other and are used to describe a polarity and direction of a voltage in a circuit. For example, the power supply may signify a high level, and the ground may signify a low level.

In comparison with a static latch, a dynamic latch does not have a feedback circuit used to maintain a working state and thus have a greatly simplified circuit structure, such that a chip area is reduced, and power consumption is decreased. With these advantages, the dynamic latch is large-scale used in computing chips. However, since there is a node with a potential floating during some period of time in the dynamic latch, parasitic capacitance at the node needs to maintain a correct voltage state during that period of time.

To avoid impact of current leakage of the device on a voltage at the node, the dynamic latch needs to operate at a high frequency to reduce leakage time, thereby preventing a functional error. This severely limits a use range of the chip. For example, in some states, such as a sleep state or an idle state, of a processor, the dynamic latch may operate at a low frequency. In this case, a functional error may occur.

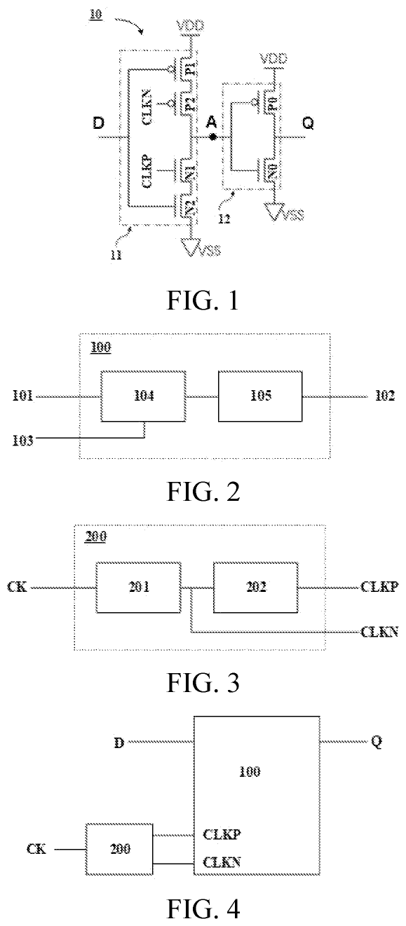

FIG. 1 shows a dynamic latch 10 according to a comparative example of the present disclosure. The dynamic latch 10 includes a tri-state gate 11 and an inverter 12 that are sequentially connected in series between a data input end D and a data output end Q. Specifically, the tri-state gate 11 includes a P-type metal-oxide-semiconductor (PMOS) transistor P1, a PMOS transistor P2, an N-type metal-oxide-semiconductor (NMOS) transistor N1, and an NMOS transistor N2 that are sequentially connected in series between a power supply VDD and ground VSS. Gates of the PMOS transistor P1 and the NMOS transistor N2 are connected together to form an input end of the tri-state gate 11. Drains of the PMOS transistor P2 and the NMOS transistor N1 are connected together to form an output end of the tri-state gate 11. Clock signals respectively received by gates of the PMOS transistor P2 and the NMOS transistor N1 are inverted with respect to each other. The inverter 12 includes a PMOS transistor P0 and an NMOS transistor N0 that are sequentially connected in series between the power supply VDD and the ground VSS. Gates of these two transistors are connected together to form an input end of the inverter 12, and drains of these two transistors are connected together to form an output end of the inverter 12. Therefore, assuming that the data input end D receives a data signal S, when a clock signal CLKP is at a high level and a clock signal CLKN is at a low level, the tri-state gate 11 is turned on, the data signal S is inverted and transmitted by the tri-state gate 11 to the inverter 12, which then is further inverted and transmitted by the inverter 12, so that the data output end Q outputs a non-inverted version of the data signal S. In other words, the dynamic latch 10 is a dynamic latch configured to provide a non-inverted output.

As shown in FIG. 1, a node A is provided between the tri-state gate 11 and the inverter 12. Data is temporarily stored on the node A by using parasitic capacitance of the inverter 12. However, during operation of the dynamic latch 10, a potential at the node A may float during part of a clock cycle. Dynamic leakage leads to loss of the data temporarily stored on the node A.

Specifically, when CLKP is at a high level, and CLKN is at a low level, the tri-state gate 11 is turned on, to transmit an inverted version of data from the data input end D to the node A, so that the inverted version of the data is written into parasitic capacitance C of the node A. When CLKP changes to a low level and CLKN changes to a high level, the tri-state gate 11 is turned off. In this case, the inverted version of the data previously transmitted by the tri-state gate 11 is held in the parasitic capacitance C of the node A.

Ideally, during a time period (referred to as an OFF period) in which CLKP is at a low level and CLKN is at a high level, the tri-state gate 11 is turned off, and the output of the dynamic latch 10 remains in an original state. At this time, the node A is in a floating state. Leakage currents of the PMOS transistor P2 and the NMOS transistor N1 may charge or discharge the node A in the floating state. When current leakage in one of the PMOS transistor P2 and the NMOS transistor N1 is more severe than that in the other of the PMOS transistor P2 and the NMOS transistor N1, a voltage state of the node A may change to an opposite state (in other words, the node A cannot maintain a correct voltage state). This undesirably changes an output state of the dynamic latch 10, resulting in a functional error in the dynamic latch 10. For example, assuming that the data input end D originally provides data “1”, and the tri-state gate 11 is turned on to cause the node A to hold data “0”; therefore, an output of the dynamic latch 10 is “1”. Then, CLKP changes to a low level, and CLKN changes to a high level, so that the PMOS transistor P2 and the NMOS transistor N1 are turned off. If, in this case, the data input end D provides data “0”, the PMOS transistor P1 is turned on and the NMOS transistor N2 is turned off. In an ideal state, even if the PMOS transistor P1 is turned on to cause a level at a source of the PMOS transistor P2 to be controlled to a high level by the power supply VDD, because the PMOS transistor P2 is turned off, the data in the node A cannot be rewritten to “1”. Therefore, an output state of the dynamic latch 10 is not changed. However, if there is current leakage in the PMOS transistor P2, and the PMOS transistor P2 cannot be fully turned off ideally, the power supply VDD charges the parasitic capacitance of the node A. On the other hand, in an ideal state, both the NMOS transistor N1 and the NMOS transistor N2 are turned off. However, if there is current leakage in the NMOS transistor N1 and the NMOS transistor N2, and the NMOS transistor N1 and the NMOS transistor N2 cannot be fully turned off ideally, the ground VSS discharges the parasitic capacitance of the node A. The charging process and the discharging process compete with each other. Once current leakage in the PMOS transistor P2 is more severe than that in the NMOS transistor N1 and the NMOS transistor N2 connected in series, the data in the node A is gradually rewritten to “1”, resulting in loss of data “0” that is supposed to be hold at the node A. Consequently, the output of the dynamic latch 10 undesirably changes to “0”. Generally, current leakage in one single PMOS transistor P2 tends to be more severe than that in the NMOS transistor N1 and the NMOS transistor N2 connected in series. Certainly, in some manufacturing processes, current leakage in an NMOS transistor may be more severe than that in a PMOS transistor, leading to an opposite situation.

Similarly, assuming that the data input end D originally provides data “0”, and the tri-state gate 11 is turned on to cause the node A to hold data “1”; therefore, an output of the dynamic latch 10 is “0”. Then, CLKP changes to a low level, and CLKN changes to a high level, so that the PMOS transistor P2 and the NMOS transistor N1 are turned off. If, in this case, the data input end D provides data “1”, the PMOS transistor P1 is turned off, and the NMOS transistor N2 is turned on. In an ideal state, even if the NMOS transistor N2 is turned on to cause a level at a source of the NMOS transistor N1 to be controlled to a low level by the ground VSS, because the NMOS transistor N1 is turned off, the data in the node A cannot be rewritten to “0”. Therefore, an output state of the dynamic latch 10 is not changed. However, if there is current leakage in the NMOS transistor N1, and the NMOS transistor N1 cannot be fully turned off ideally, the ground VSS discharges the parasitic capacitance of the node A. On the other hand, in an ideal state, both the PMOS transistor P1 and the PMOS transistor P2 are turned off. However, if there is current leakage in the PMOS transistor P1 and the PMOS transistor P2, and the PMOS transistor P1 and the PMOS transistor P2 cannot be fully turned off ideally, the power supply VDD charges the parasitic capacitance of the node A. The charging process and the discharging process compete with each other. Once current leakage in the NMOS transistor N1 is more severe than that in the PMOS transistor P1 and the PMOS transistor P2 connected in series, the data in the node A is gradually rewritten to “0”, resulting in loss of data “1” that is supposed to be held at the node A. Consequently, the output of the dynamic latch 10 undesirably changes to “1”. Generally, current leakage in one single NMOS transistor N1 tends to be more severe than that in the PMOS transistor P1 and the PMOS transistor P2 connected in series. Certainly, in some manufacturing processes, current leakage in a PMOS transistor may be more severe than that in an NMOS transistor, leading to an opposite situation.

In other words, in a state where CLKP is at a low level and CLKN is at a high level, the tri-state gate 11 may not ideally remain off. Instead, some leakage path exits. Especially as the OFF period gets longer, a data loss risk gets higher. However, as the manufacturing process node continues to shrink (for example, 7 nanometers, 5 nanometers, etc.), current leakage in both an NMOS transistor and a PMOS transistor gets more severe, and leakage imbalance between the two transistors may also be intensified accordingly. This requires the OFF period to be shorter and shorter.

Specifically, assuming that charge stored on the parasitic capacitance C is Q, a capacitance value of the parasitic capacitance C is C, and a voltage across the parasitic capacitance C is V, then Q=C*V. If a leakage current is I_{leakage}, leakage time T (corresponding to the OFF period) is T=Q/I_{leakage}=C*V/I_{leakage}. The leakage time is directly proportional to the clock cycle, that is, a clock frequency F_{clk}∝1/T=I_{leakage}/(C*V). Therefore, dynamic leakage limits a minimum operating frequency of the dynamic latch. If an operating frequency of the dynamic latch is excessively low, a functional error may occur.

Therefore, the present disclosure provides a dynamic latch which can effectively suppress the dynamic leakage, thereby enabling normal operation at a lower operating frequency. This is beneficial to reducing power consumption. Especially when such a dynamic latch is large-scale used in a computing chip, overall power consumption of the computing chip can be significantly reduced. The dynamic latch according to various embodiments of the present disclosure is described below in detail with reference to the accompanying drawings. It should be understood that an actual dynamic latch may further include other components. However, to avoid obscuring main points of the present disclosure, these other components are not discussed in this specification and are not shown in the accompanying drawings.

FIG. 2 shows a dynamic latch 100 according to some embodiments of the present disclosure. The dynamic latch 100 includes a data input end 101, a data output end 102, a clock control end 103, and includes a latch unit 104 and an inverting drive unit 105 that are sequentially connected in series between the data input end 101 and the data output end 102. The data input end 101 is configured to receive a data signal. The data output end 102 is configured to output the data signal. The clock control end 103 is configured to receive a clock signal. The latch unit 104 is configured to latch or transmit the data signal from the data input end 101 under control of the clock signal. The inverting drive unit 105 is configured to invert and transmit the data signal from the latch unit 104.

FIG. 3 shows a clock buffer 200 configured to provide the clock signal. The clock buffer 200 includes an inverter 201 and an inverter 202 that form two stages and are connected in series. The clock buffer 200 buffers an input clock signal CK and provides a clock signal CLKN and a clock signal CLKP that are inverted with respect to each other. FIG. 3 shows only two inverters. Certainly, a number of inverters is not limited to two, but there may be more inverters. The clock buffer 200 may be configured to provide the clock signal for the dynamic latch 100. As shown in FIG. 4, the clock buffer 200 buffers the clock signal CK, and then provides, for the dynamic latch 100, the clock signal CLKN and the clock signal CLKP that are inverted with respect to each other. Similarly, the clock buffer 200 may be configured to provide the clock signal CLKN and the clock signal CLKP that are inverted with respect to each other for a dynamic D flip-flop, a register, and the like that are described later.

For example, the latch unit 104 may include a latch circuit according to various embodiments of the present disclosure. Such a latch circuit may be configured as a latch circuit for providing an inverted output. Specifically, the latch circuit may include: an input end; an output end; and a first transistor group of a first conduction type, a second transistor group of the first conduction type, a third transistor group of a second conduction type different from the first conduction type, and a fourth transistor group of the second conduction type that are sequentially connected in series between a power supply and ground. As described above, the first conduction type is configured such that a transistor is turned on when a control end of the transistor is at a low level, and the second conduction type is configured such that a transistor is turned on when a control end of the transistor is at a high level.

A node between the second transistor group and the third transistor group is connected to the output end for outputting the data signal. A control end of one of the first transistor group and the second transistor group and a control end of one of the third transistor group and the fourth transistor group are jointly connected to the input end for receiving the data signal. A control end of the other of the first transistor group and the second transistor group is configured to receive a first clock signal. A control end of the other of the third transistor group and the fourth transistor group is configured to receive a second clock signal that is inverted with respect to the first clock signal. In this specification, a transistor or a transistor group configured to receive a data signal may be referred to as a data transistor or a data transistor group. A transistor or a transistor group configured to receive a clock signal may be referred to as a clock transistor or a clock transistor group. In addition, a circuit portion from the power supply to the output end may be referred to as a first sub-circuit, and the first sub-circuit includes the first transistor group and the second transistor group. A circuit portion from the ground to the output end may be referred to as a second sub-circuit, and the second sub-circuit includes the third transistor group and the fourth transistor group.

In particular, at least one transistor group of the first to fourth transistor groups includes a plurality of transistors connected in series, so that current leakage at the at least one transistor group can be reduced, thereby lowering the minimum operating frequency.

In some embodiments, the at least one transistor group may be a clock transistor group. For example, the at least one transistor group includes one or more clock transistor groups. In some embodiments, the at least one transistor group may be a data transistor group. For example, the at least one transistor group includes one or more data transistor groups. In some embodiments, transistor groups in the at least one transistor group includes at least one data transistor group and at least one clock transistor group. In most cases, it may be more advantageous to have a clock transistor group include a plurality of transistors connected in series than to have a data transistor group include a plurality of transistors connected in series. This is because, as analyzed above in respect of FIG. 1, current leakage in a clock transistor is more likely to cause a data loss (a data transistor would be connected in series to a corresponding clock transistor in a corresponding leakage path; in comparison with another leakage path with only one single clock transistor, the corresponding leakage path may cause a slighter current leakage due to the presence of more transistors, and the corresponding leakage path is more likely to repair data held at the node A than the another leakage path). Certainly, in some aspects, it may be advantageous to have a clock transistor group include a plurality of transistors connected in series and further have a data transistor group include a plurality of transistors connected in series, because leakage can be further suppressed in this way. However, too many transistors may cause problems such as occupying an excessively large chip area and slowing down an operation speed.

As a non-limiting embodiment, the control end of the first transistor group and the control end of the fourth transistor group may be jointly connected to the input end, the control end of the second transistor group is configured to receive the first clock signal, and the control end of the third transistor group is configured to receive the second clock signal. In such an embodiment, the first transistor group and the fourth transistor group serve as data transistor groups, and the second transistor group and the third transistor group serve as clock transistor groups. In some examples, at least one of the second transistor group or the third transistor group includes a plurality of transistors connected in series. Further, in some examples, at least one of the first transistor group or the fourth transistor group includes a plurality of transistors connected in series.

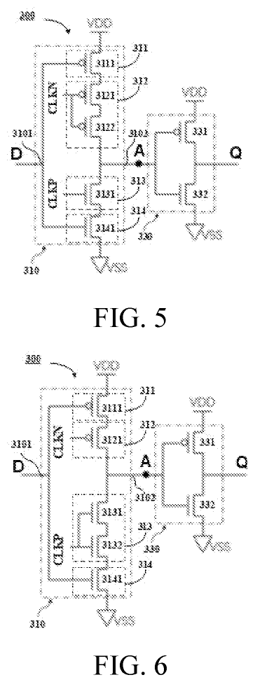

For example, FIG. 5 shows a circuit 300 of the dynamic latch 100 according to some embodiments of the present disclosure. As shown in FIG. 5, the circuit 300 includes a latch circuit 310 (which serves as the latch unit 104 (specifically, an inverting latch unit) of the dynamic latch 100) and an inverter 330 (which serves as the inverting drive unit 105 of the dynamic latch 100) that are sequentially connected in series between a data input end D and a data output end Q.

The inverter 330 includes a PMOS transistor 331 and an NMOS transistor 332 that are sequentially connected in series between a power supply VDD and ground VSS. Control ends (which are gates here) of the two transistors are connected together to form an input end of the inverter 330, and transmission ends (which are drains here) of the two transistors are connected together to form an output end of the inverter 330. The output end of the inverter 330 may directly provide the data output end Q of the circuit 300.

The latch circuit 310 includes an input end 3101 and an output end 3102. The input end 3101 of the latch circuit 310 may directly provide the data input end D of the circuit 300. The output end 3102 of the latch circuit 310 is connected to the input end of the inverter 330, with a node A where potential floats at some times formed therebetween.

As shown in FIG. 5, the latch circuit 310 includes a PMOS transistor group 311, a PMOS transistor group 312, an NMOS transistor group 313, and an NMOS transistor group 314 that are sequentially connected in series between the power supply VDD and the ground VSS. A control end (which is a gate here) of the PMOS transistor group 311 and a control end (which is a gate here) of the NMOS transistor group 314 are jointly connected to the input end 3101. A node between the PMOS transistor group 312 and the NMOS transistor group 313 is connected to the output end 3102. In particular, the PMOS transistor group 311 includes one PMOS transistor 3111, the PMOS transistor group 312 includes two PMOS transistors 3121, 3122 that are connected in series, the NMOS transistor group 313 includes one NMOS transistor 3131, and the NMOS transistor group 314 includes one NMOS transistor 3141. Generally, none of substrate regions (bulks) of these transistors are floated. Substrate regions of the PMOS transistors may be connected to the power supply, and substrate regions of the NMOS transistors may be grounded.

In the example of FIG. 5, the PMOS transistor group 312 is configured to receive a clock signal CLKN, and the NMOS transistor group 313 is configured to receive a clock signal CLKP that is inverted with respect to the clock signal CLKN. Specifically, control ends (which are gates here) of the PMOS transistor 3121 and the PMOS transistor 3122 may be connected together to receive the clock signal CLKN, and a control end (which is a gate here) of the NMOS transistor 3131 receives the clock signal CLKP.

In comparison with the dynamic latch 10 in FIG. 1, in FIG. 5, including a plurality of PMOS transistors connected in series in the PMOS transistor group configured to receive the clock signal equivalently achieves a channel-extended PMOS transistor configured to receive the clock signal, so that leakage currents are reduced, thereby lowering the minimum operating frequency.

This is especially advantageous in a digital circuit, because, unlike an analog circuit allowing for flexibly designing a size of a transistor, the digital circuit usually uses a transistor from a standard cell library. Options for the channel length of a transistor in the standard cell library are limited. Generally, there are two levels, one with 1 unit length and the other with 1.2 unit length. Channel extension provided by simply replacing a transistor having a channel of 1 unit length with a transistor having a channel of 1.2 unit length cannot sufficiently suppress dynamic leakage. A leakage current of a transistor can also be reduced by increasing a threshold voltage VTH of the transistor. However, options for a threshold voltage of a transistor in the standard cell library are also limited. In addition, an excessively large change caused by increasing a threshold voltage may cause it more difficult to turn on a transistor (for example, a power supply voltage needs to be increased). In this case, accurate suppression of the dynamic leakage cannot be achieved. Therefore, a desired channel extension effect can be achieved by controlling a number of transistors connected in series in a transistor group based on a specific requirement, thereby sufficiently suppressing the dynamic leakage. Certainly, it is not appropriate to include an excessively large number of transistors, which may reduce the speed of the dynamic latch. In some examples, a number of transistors in each of the at least one transistor group of the first to fourth transistor groups does not exceed three; for example, two transistors are included.

FIG. 6 shows the circuit 300 of the dynamic latch 100 according to some other embodiments of the present disclosure. In comparison with FIG. 5, in FIG. 6, the PMOS transistor group 312 includes one PMOS transistor 3121, and the NMOS transistor group 313 includes two NMOS transistors 3131, 3132 that are connected in series. The control end (which is a gate here) of the PMOS transistor 3121 receives the clock signal CLKN, and the control ends (which are gates here) of the NMOS transistor 3131 and the NMOS transistor 3132 may be connected together to receive the clock signal CLKP. In comparison with the dynamic latch 10 in FIG. 1, in FIG. 6, including a plurality of NMOS transistors connected in series in the NMOS transistor group configured to receive the clock signal equivalently achieves a channel-extended NMOS transistor configured to receive the clock signal, so that leakage currents are reduced, thereby lowering the minimum operating frequency.

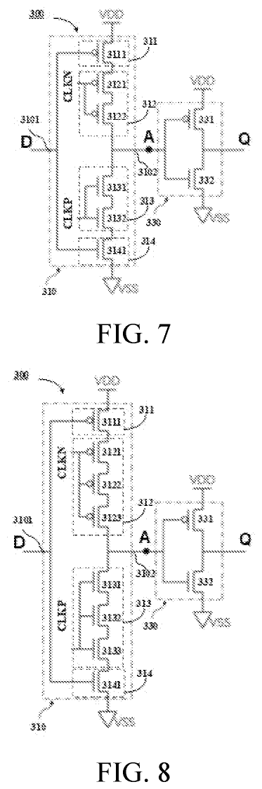

FIG. 7 shows the circuit 300 of the dynamic latch 100 according to some other embodiments of the present disclosure. In comparison with FIG. 5, in FIG. 7, the NMOS transistor group 313 includes two NMOS transistors 3131, 3132 that are connected in series. In comparison with the dynamic latch 10 in FIG. 1, in FIG. 7, including a plurality of PMOS transistors connected in series in the PMOS transistor group configured to receive the clock signal and including a plurality of NMOS transistors connected in series in the NMOS transistor group configured to receive the clock signal equivalently achieve a channel-extended PMOS transistor configured to receive the first clock signal and a channel-extended NMOS transistor configured to receive the second clock signal, so that leakage currents are reduced, thereby lowering the minimum operating frequency.

FIG. 8 shows the circuit 300 of the dynamic latch 100 according to some other embodiments of the present disclosure. In comparison with FIG. 7, in FIG. 8, the PMOS transistor group 312 includes three PMOS transistor 3121, 3122, and 3123 that are connected in series, and the NMOS transistor group 313 includes three NMOS transistor 3131, 3132, and 3133 that are connected in series. Control ends (which are gates here) of the PMOS transistor 3121, the PMOS transistor 3122, and the PMOS transistor 3123 may be connected together to receive the clock signal CLKN, and control ends (which are gates here) of the NMOS transistor 3131, the NMOS transistor 3132, and the NMOS transistor 3133 may be connected together to receive the clock signal CLKP. In comparison with FIG. 7, in FIG. 8, a number of transistors connected in series in each clock transistor group changes from two to three. As described above, current leakage may be further suppressed, so that the minimum operating frequency is further lowered.

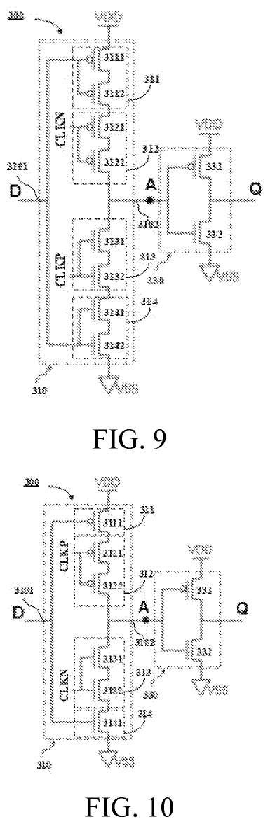

FIG. 9 shows the circuit 300 of the dynamic latch 100 according to some other embodiments of the present disclosure. In comparison with FIG. 7, in FIG. 9, the PMOS transistor group 311 includes two PMOS transistors 3111, 3112 that are connected in series, and the NMOS transistor group 314 includes two NMOS transistors 3141, 3142 that are connected in series. Control ends (which are gates here) of the PMOS transistor 3111, the PMOS transistor 3112, the NMOS transistor 3141, and the NMOS transistor 3142 may be connected together to the input end 3101. In comparison with FIG. 7, in FIG. 9, including a plurality of PMOS transistors connected in series in the PMOS transistor group configured to receive the data signal and including a plurality of NMOS transistors connected in series in the NMOS transistor group configured to receive the data signal equivalently achieve a channel-extended PMOS transistor configured to receive the data signal and a channel-extended NMOS transistor configured to receive the data signal, so that leakage currents are reduced, thereby lowering the minimum operating frequency.

A number of transistors in each of the two transistor groups may be respectively adjusted based on an actual requirement. For example, when current leakage in an NMOS transistor is more severe than that in a PMOS transistor due to a transistor manufacturing process, a number of transistors included in an NMOS transistor group may be greater than a number of transistors included in a PMOS transistor group. On the contrary, when current leakage in a PMOS transistor is more severe than that in an NMOS transistor due to a transistor manufacturing process, a number of transistors included in a PMOS transistor group may be greater than a number of transistors included in an NMOS transistor group. Generally, a higher level of balance in current leakage between the first sub-circuit and the second sub-circuit makes it more difficult to change a voltage state of the floating node A to an opposite state, so that a functional error can be prevented.

Therefore, in some embodiments, a total number of transistors in the first transistor group and the second transistor group may be greater than a total number of transistors in the third transistor group and the fourth transistor group. Additionally, or alternatively, in some embodiments, a number of transistors in a clock transistor group in the first transistor group and the second transistor group may be greater than a number of transistors in a clock transistor group in the third transistor group and the fourth transistor group. This is, for example, shown in FIG. 5. In such embodiments, a transistor of the first conduction type may exhibit more severe current leakage than a transistor of the second conduction type.

In some other embodiments, a total number of transistors in the first transistor group and the second transistor group may be less than a total number of transistors in the third transistor group and the fourth transistor group. Additionally, or alternatively, in some embodiments, a number of transistors in a clock transistor group in the first transistor group and the second transistor group may be less than a number of transistors in a clock transistor group in the third transistor group and the fourth transistor group. This is, for example, shown in FIG. 6. In such embodiments, a transistor of the second conduction type may exhibit more severe current leakage than a transistor of the first conduction type.

In still some other embodiments, a total number of transistors in the first transistor group and the second transistor group may be equal to a total number of transistors in the third transistor group and the fourth transistor group. Additionally, or alternatively, in some embodiments, a number of transistors in a clock transistor group in the first transistor group and the second transistor group may be equal to a number of transistors in a clock transistor group in the third transistor group and the fourth transistor group. This is, for example, shown in FIG. 7 and FIG. 8. In such embodiments, a transistor of the first conduction type may exhibit substantially the same degree of current leakage as a transistor of the second conduction type. For example, in this specification, “substantially the same degree of current leakage” may refer to a situation where a difference between degrees of current leakage does not exceed 20%, or 15%, or 10%, or 5%.

Although the embodiments shown in FIG. 5 to FIG. 9 depict that a number of transistors in a P-type data transistor group (for example, the PMOS transistor group 311) is the same as a number of transistors in an N-type data transistor group (for example, the NMOS transistor group 314), this is merely an example and is not intended to impose any limitations. A number of transistors in a data transistor group may also be adjusted individually or in combination with a number of transistors in a clock transistor group based on the foregoing teachings. Details are not described herein.

In the foregoing circuit 300, the dynamic latch is active high. For example, with reference to FIG. 7 to FIG. 27, at the beginning, input data at the data input end D is “0”, and the data output end Q provides non-inverted output data “0”. Next, the input data at the data input end D changes from “0” to “1”. However, because, at this time, CLKP is at a low level and CLKN is at a high level, and the latch circuit 310 is turned off. Therefore, the data output end Q still holds “0”. As CLKP changes to a high level and CLKN changes to a low level, the latch circuit 310 is turned on. The input data “1” at the data input end D is inverted and transmitted by the latch circuit 310 and then inverted and transmitted by the inverter 330, so that the data output end Q provides non-inverted output data “1”.

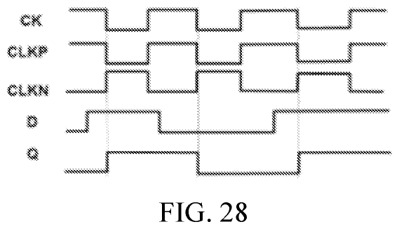

In addition, application of the clock signal CLKP and the clock signal CLKN in any one of embodiments herein may be swapped. For example, with reference to FIG. 10, in comparison with FIG. 7, application of the clock signal CLKP and the clock signal CLKN is swapped, so that the PMOS transistor group 312 receives the clock signal CLKP and the NMOS transistor group 313 receives the clock signal CLKN, thereby implementing a dynamic latch that is active low. For example, with reference to FIG. 10 to FIG. 28, at the beginning, input data at the data input end D is “0”, and the data output end Q provides non-inverted output data “0”. Next, the input data at the data input end D changes from “0” to “1”. However, because, at this time, CLKP is at a high level and CLKN is at a low level, the latch circuit 310 is turned off. Therefore, the data output end Q still holds “0”. As CLKP changes to a low level and CLKN changes to a high level, the latch circuit 310 is turned on. The input data “1” at the data input end D is inverted and transmitted by the latch circuit 310 and then inverted and transmitted by the inverter 330, so that the data output end Q provides non-inverted output data “1”.

As another non-limiting embodiment, the control end of the second transistor group and the control end of the third transistor group may be jointly connected to the input end, the control end of the first transistor group is configured to receive the first clock signal, and the control end of the fourth transistor group is configured to receive the second clock signal. In such an embodiment, the first transistor group and the fourth transistor group serve as clock transistor groups, and the second transistor group and the third transistor group serve as data transistor groups. In some examples, at least one of the first transistor group or the fourth transistor group includes a plurality of transistors connected in series. Further, in some examples, at least one of the second transistor group or the third transistor group includes a plurality of transistors connected in series.

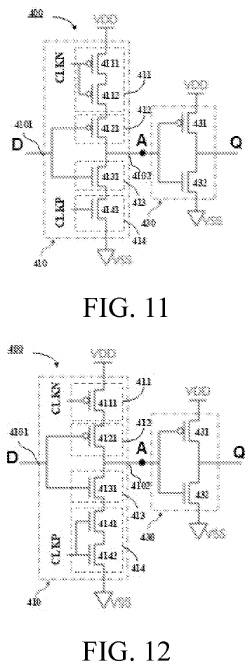

For example, FIG. 11 shows a circuit 400 of the dynamic latch 100 according to some embodiments of the present disclosure. As shown in FIG. 11, the circuit 400 includes a latch circuit 410 (which serves as the latch unit 104 (specifically, an inverting latch unit) of the dynamic latch 100) and an inverter 430 (which serves as the inverting drive unit 105 of the dynamic latch 100) that are sequentially connected in series between a data input end D and a data output end Q.

Similar to the inverter 330, the inverter 430 includes a PMOS transistor 431 and an NMOS transistor 432 that are sequentially connected in series between a power supply VDD and ground VSS. The output end of the inverter 430 may directly provide the data output end Q of the circuit 400.

Similar to the latch circuit 310, the latch circuit 410 includes an input end 4101 and an output end 4102. The input end 4101 of the latch circuit 410 may directly provide the data input end D of the circuit 400. The output end 4102 of the latch circuit 410 is connected to the input end of the inverter 430, with a node A where potential floats at some times formed therebetween.

As shown in FIG. 11, the latch circuit 410 includes a PMOS transistor group 411, a PMOS transistor group 412, an NMOS transistor group 413, and an NMOS transistor group 414 that are sequentially connected in series between the power supply VDD and the ground VSS. A control end (which is a gate here) of the PMOS transistor group 412 and a control end (which is a gate here) of the NMOS transistor group 413 are jointly connected to the input end 4101. A node between the PMOS transistor group 412 and the NMOS transistor group 413 is connected to the output end 4102. The PMOS transistor group 411 includes two PMOS transistors 4111, 4112 that are connected in series, the PMOS transistor group 412 includes one PMOS transistor 4121, the NMOS transistor group 413 includes one NMOS transistor 4131, and the NMOS transistor group 414 includes one NMOS transistor 4141. Generally, none of substrate regions (bulks) of these transistors are floated. Substrate regions of the PMOS transistors may be connected to the power supply, and substrate regions of the NMOS transistors may be grounded.

In the example of FIG. 11, the PMOS transistor group 411 is configured to receive a clock signal CLKN, and the NMOS transistor group 414 is configured to receive a clock signal CLKP that is inverted with respect to the clock signal CLKN.

In comparison with the dynamic latch 10 in FIG. 1, in FIG. 11, including a plurality of PMOS transistors connected in series in the PMOS transistor group configured to receive the clock signal equivalently achieves a channel-extended PMOS transistor configured to receive the clock signal, so that leakage currents are reduced, thereby lowering the minimum operating frequency.

FIG. 12 shows the circuit 400 of the dynamic latch 100 according to some other embodiments of the present disclosure. In comparison with FIG. 11, in FIG. 12, the PMOS transistor group 411 includes one PMOS transistor 4111, and the NMOS transistor group 414 includes two NMOS transistors 4141, 4142 that are connected in series. In comparison with the dynamic latch 10 in FIG. 1, in FIG. 12, including a plurality of NMOS transistors connected in series in the NMOS transistor group configured to receive the clock signal equivalently achieves a channel-extended NMOS transistor configured to receive the clock signal, so that leakage currents are reduced, thereby lowering the minimum operating frequency.

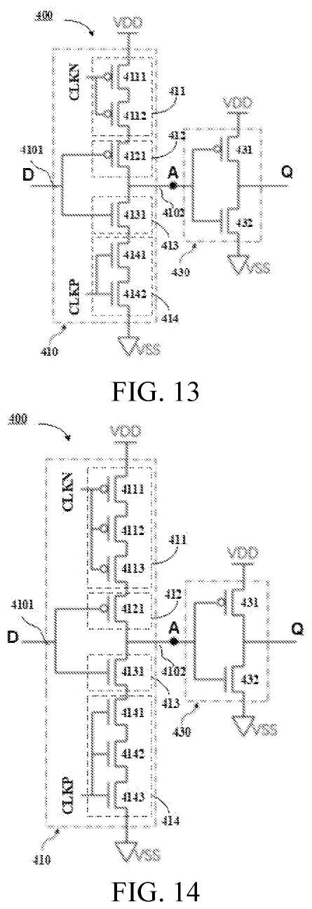

FIG. 13 shows the circuit 400 of the dynamic latch 100 according to some other embodiments of the present disclosure. In comparison with FIG. 11, in FIG. 13, the NMOS transistor group 414 includes two NMOS transistors 4141, 4142 that are connected in series. In comparison with the dynamic latch 10 in FIG. 1, in FIG. 13, including a plurality of PMOS transistors connected in series in the PMOS transistor group configured to receive the clock signal and including a plurality of NMOS transistors connected in series in the NMOS transistor group configured to receive the clock signal equivalently achieve a channel-extended PMOS transistor configured to receive the first clock signal and a channel-extended NMOS transistor configured to receive the second clock signal, so that leakage currents are reduced, thereby lowering the minimum operating frequency.

FIG. 14 shows the circuit 400 of the dynamic latch 100 according to some other embodiments of the present disclosure. In comparison with FIG. 13, in FIG. 14, the PMOS transistor group 411 includes three PMOS transistors 4111, 4112, and 4113 that are connected in series, and the NMOS transistor group 414 includes three NMOS transistors 4141, 4142, and 4143 that are connected in series. In comparison with FIG. 13, in FIG. 14, a number of transistors connected in series in each clock transistor group changes from two to three. As described above, current leakage can be further suppressed, so that the minimum operating frequency is further lowered.

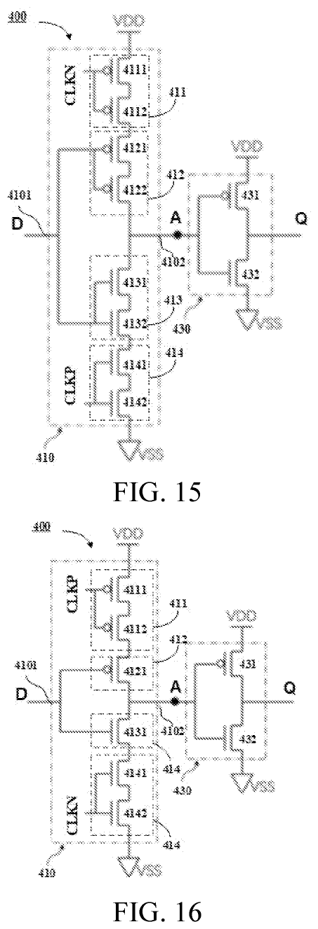

FIG. 15 shows the circuit 400 of the dynamic latch 100 according to some other embodiments of the present disclosure. In comparison with FIG. 13, in FIG. 15, the PMOS transistor group 412 includes two PMOS transistors 4121, 4122 that are connected in series, and the NMOS transistor group 413 includes two NMOS transistors 4131, 4132 that are connected in series. In comparison with FIG. 13, in FIG. 15, including a plurality of PMOS transistors connected in series in the PMOS transistor group configured to receive the data signal and including a plurality of NMOS transistors connected in series in the NMOS transistor group configured to receive the data signal equivalently achieve a channel-extended PMOS transistor configured to receive the data signal and a channel-extended NMOS transistor configured to receive the data signal, so that leakage currents are reduced, thereby lowering the minimum operating frequency.

FIG. 16 shows the circuit 400 of the dynamic latch 100 according to some other embodiments of the present disclosure. In comparison with FIG. 13, application of the clock signal CLKP and the clock signal CLKN is swapped, so that the PMOS transistor group 411 receives the clock signal CLKP and the NMOS transistor group 414 receives the clock signal CLKN, thereby implementing a dynamic latch that is active low.

As a non-limiting embodiment, the control end of the first transistor group and the control end of the third transistor group may be jointly connected to the input end, the control end of the second transistor group is configured to receive the first clock signal, and the control end of the fourth transistor group is configured to receive the second clock signal. In such an embodiment, the second transistor group and the fourth transistor group serve as clock transistor groups, and the first transistor group and the third transistor group serve as data transistor groups. In some examples, at least one of the second transistor group or the fourth transistor group includes a plurality of transistors connected in series. Further, in some examples, at least one of the first transistor group or the third transistor group includes a plurality of transistors connected in series.

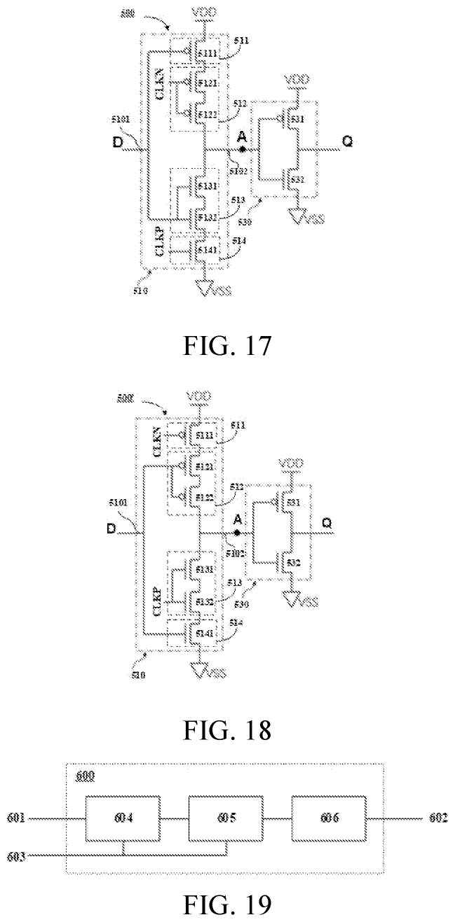

For example, FIG. 17 shows a circuit 500 of the dynamic latch 100 according to some embodiments of the present disclosure. As shown in FIG. 17, the circuit 500 includes a latch circuit 510 (which serves as the latch unit 104 (specifically, an inverting latch unit) of the dynamic latch 100) and an inverter 530 (which serves as the inverting drive unit 105 of the dynamic latch 100) that are sequentially connected in series between a data input end D and a data output end Q.

Similar to the inverter 330, the inverter 530 includes a PMOS transistor 531 and an NMOS transistor 532 that are sequentially connected in series between a power supply VDD and ground VSS. The output end of the inverter 530 may directly provide the data output end Q of the circuit 500.

Similar to the latch circuit 310, the latch circuit 510 includes an input end 5101 and an output end 5102. The input end 5101 of the latch circuit 510 may directly provide the data input end D of the circuit 500. The output end 5102 of the latch circuit 510 is connected to the input end of the inverter 530, with a node A where potential floats at some times formed therebetween. As shown in FIG. 17, the latch circuit 510 includes a PMOS transistor group 511, a PMOS transistor group 512, an NMOS transistor group 513, and an NMOS transistor group 514 that are sequentially connected in series between the power supply VDD and the ground VSS. The PMOS transistor group 511 includes one PMOS transistor 5111, the PMOS transistor group 512 includes two PMOS transistors 5121, 5122 that are connected in series, the NMOS transistor group 513 includes two NMOS transistors 5131, 5132 that are connected in series, and the NMOS transistor group 514 includes one NMOS transistor 5141. Generally, none of substrate regions (bulks) of these transistors are floated. Substrate regions of the PMOS transistors may be connected to the power supply, and substrate regions of the NMOS transistors may be grounded.

In the example of FIG. 17, the PMOS transistor group 512 is configured to receive a clock signal CLKN, and the NMOS transistor group 514 is configured to receive a clock signal CLKP that is inverted with respect to the clock signal CLKN. In comparison with the dynamic latch 10 in FIG. 1, in FIG. 17, including a plurality of PMOS transistors connected in series in the PMOS transistor group configured to receive the clock signal equivalently achieves a channel-extended PMOS transistor configured to receive the clock signal, so that leakage currents are reduced, thereby lowering the minimum operating frequency.

As another non-limiting embodiment, the control end of the second transistor group and the control end of the fourth transistor group may be jointly connected to the input end, the control end of the first transistor group is configured to receive the first clock signal, and the control end of the third transistor group is configured to receive the second clock signal. In such an embodiment, the second transistor group and the fourth transistor group serve as data transistor groups, and the first transistor group and the third transistor group serve as clock transistor groups. In some examples, at least one of the first transistor group or the third transistor group includes a plurality of transistors connected in series. Further, in some examples, at least one of the second transistor group or the fourth transistor group includes a plurality of transistors connected in series.

For example, FIG. 18 shows a circuit 500′ of the dynamic latch 100 according to some embodiments of the present disclosure. In comparison with the circuit 500 in FIG. 17, in the circuit 500′, the PMOS transistor group 511 is configured to receive a clock signal CLKN, the NMOS transistor group 513 is configured to receive a clock signal CLKP that is inverted with respect to the clock signal CLKN, and the PMOS transistor group 512 and the NMOS transistor group 514 are each configured to receive a data signal.

In comparison with the circuit 300, the circuit 400, the circuit 500 and the circuit 500′ each configure different transistor groups among the first transistor group to the fourth transistor group as clock transistor groups and data transistor groups, while they are similar to the circuit 300 in other aspects. Therefore, for related parts, reference may be made to the various embodiments of the circuit 300. Details are not described herein again.

In another aspect, the present disclosure further provides a dynamic D flip flop which can effectively suppress dynamic leakage, thereby enabling normal operation at a lower operating frequency. This is beneficial to reducing power consumption. Especially when such a dynamic D flip-flop is large-scale used in a computing chip, overall power consumption of the computing chip can be significantly reduced. The dynamic D flip-flop according to various embodiments of the present disclosure is described below in detail with reference to the accompanying drawings. It should be understood that an actual dynamic D flip-flop may further include other components. However, to avoid obscuring main points of the present disclosure, these other components are not discussed in this specification and are not shown in the accompanying drawings. It should be further understood that a latch circuit included in the dynamic D flip-flop depicted in subsequent accompanying drawings is merely an example and is not intended to impose any limitation, and may be replaced with the latch circuit according to any one of embodiments of the present disclosure.

FIG. 19 shows a dynamic D flip-flop 600 according to some embodiments of the present disclosure. The dynamic D flip-flop 600 includes a data input end 601, a data output end 602, a clock control end 603, and includes a first latch unit 604, a second latch unit 605, and an inverting drive unit 606 that are sequentially connected in series between the data input end 601 and the data output end 602. The data input end 601 is configured to receive a data signal. The data output end 602 is configured to output the data signal. The clock control end 603 is configured to receive a clock signal. The first latch unit 604 is configured to latch or transmit the data signal from the data input end 601 under control of the clock signal. The second latch unit 605 is configured to latch or transmit the data signal from the first latch unit 604 under control of the clock signal. The inverting drive unit 606 is configured to invert and transmit the data signal from the second latch unit 605.

In comparison with a static D flip-flop, a dynamic D flip-flop does not have a feedback circuit used to maintain a working state and thus have a greatly simplified circuit structure, such that a chip area is reduced, and power consumption is decreased. With these advantages, the dynamic D flip-flop is large-scale used in computing chips. However, since there is a node with a potential floating during some period of time in the dynamic D flip-flop (for example, a node formed between the first latch unit 604 and the second latch unit 605 and a node formed between the second latch unit 605 and the inverting drive unit 606), parasitic capacitance at the node needs to maintain a correct voltage state during that period of time. To avoid impact of current leakage of the device on a voltage at the node, the dynamic D flip-flop needs to operate at a high frequency to reduce leakage time, thereby preventing a functional error. This severely limits a use range of the chip. For example, in some states, such as a sleep state or an idle state, of a processor, the dynamic D flip-flop may operate at a low frequency. In this case, a functional error may occur.

In some embodiments, the first latch unit 604 includes the latch circuit according to any one of embodiments of the present disclosure. An input end of such a latch circuit, for example, may directly provide the data input end 601 of the dynamic D flip-flop. As described above, by using the latch circuit of the present disclosure in the first latch unit 604, a leakage current can be effectively suppressed, so that a minimum operating frequency of the dynamic D flip-flop is lowered.

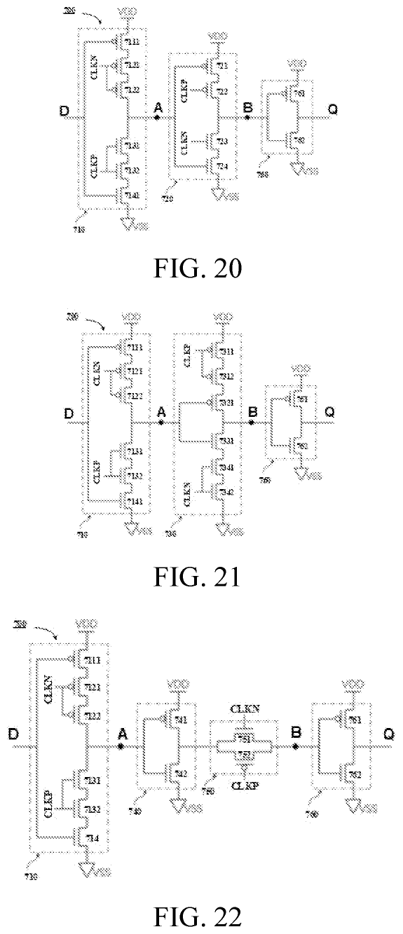

In some examples, the second latch unit 605 may include a tri-state gate. For example, FIG. 20 shows a circuit 700 of the dynamic D flip-flop 600 according to some embodiments of the present disclosure. As shown in FIG. 20, the circuit 700 includes a latch circuit 710 (which serves as the first latch unit 604 (specifically, an inverting latch unit) of the dynamic D flip-flop 600), a tri-state gate 720 (which serves as the second latch unit 605 (specifically, an inverting latch unit) of the dynamic D flip-flop 600), and an inverter 760 (which serves as the inverting drive unit 606 of the dynamic D flip-flop 600) that are sequentially connected in series between a data input end D and a data output end Q. Potential at a node A formed between the latch circuit 710 and the tri-state gate 720 and potential at a node B formed between the tri-state gate 720 and the inverter 760 float at some times.

The latch circuit 710 includes a PMOS transistor 7111, a PMOS transistor 7121, a PMOS transistor 7122, an NMOS transistor 7131, an NMOS transistor 7132, and an NMOS transistor 7141 arranged as in the example shown in FIG. 7, which does not mean any limitation. The inverter 760 includes a PMOS transistor 761 and an NMOS transistor 762 that are sequentially connected in series between a power supply VDD and ground VSS. The tri-state gate 720 includes a PMOS transistor 721, a PMOS transistor 722, an NMOS transistor 723, and an NMOS transistor 724 that are sequentially connected in series between the power supply VDD and the ground VSS. In particular, the NMOS transistor 7131, the NMOS transistor 7132, and the PMOS transistor 722 receive a clock signal CLKP, and the PMOS transistor 7121, the PMOS transistor 7122, and the NMOS transistor 723 receive a clock signal CLKN. In this case, the clock signals may cause the tri-state gate 720 to be turned on when the latch circuit 710 is turned off and to be turned off when the latch circuit 710 is turned on. Therefore, when CLKP is at a high level and CLKN is at a low level, the latch circuit 710 is turned on, and the tri-state gate 720 is turned off. Data from the data input end D is inverted and transmitted by the latch circuit 710 and then outputted to the node A (for example, data of the node A is rewritten), but cannot continue to pass through the tri-state gate 720. When CLKP changes to a low level and CLKN changes to a high level, the latch circuit 710 is turned off, and the tri-state gate 720 is turned on. Data from the data input end D cannot pass through the latch circuit 710, so that the data of the node A is held. The data from the node A is inverted and transmitted by the tri-state gate 720 and then outputted to the node B (for example, data of the node B is rewritten), and is further inverted and transmitted by the inverter 760 and then outputted to the data output end Q. When CLKP changes to a high level again and CLKN changes to a low level again, the latch circuit 710 is turned on, and the tri-state gate 720 is turned off. Data from the data input end D is inverted and transmitted by the latch circuit 710 and then outputted to the node A (for example, data of the node A is rewritten), but cannot continue to pass through the tri-state gate 720, so that the data of the node B is held. Similarly, application of the clock signals CLKP and CLKN may also be swapped, so that an active level also changes accordingly. In addition, the arrangement of the tri-state gate 720 is not limited to this, and may alternatively be replaced with the following arrangement: gates of the PMOS transistor 721 and the NMOS transistor 724 receive respective clock signals, and gates of the PMOS transistor 722 and the NMOS transistor 723 are connected together to receive a data signal. The tri-state gate mentioned in other parts of this specification is also similar, and details are not described herein again.

In some embodiments, the second latch unit 605 may include the latch circuit according to any one of embodiments of the present disclosure. For example, with reference to FIG. 21 and in comparison with FIG. 20, the tri-state gate 720 is replaced with a latch circuit 730, which serves as the second latch unit 605 (specifically, an inverting latch unit) of the dynamic D flip-flop 600. The latch circuit 730 includes a PMOS transistor 7311, a PMOS transistor 7312, a PMOS transistor 7321, an NMOS transistor 7331, an NMOS transistor 7341, and an NMOS transistor 7342 arranged as in the example shown in FIG. 13, which does not mean any limitation. Therefore, the latch circuit 710 can reduce the impact of dynamic leakage in the node A, and the latch circuit 730 can reduce the impact of dynamic leakage in the node B, so that the minimum operating frequency of the dynamic D flip-flop is further lowered. Time sequence control in FIG. 21 is similar to that in FIG. 20, and details are not described herein again.

In some examples, the second latch unit 605 may include an inverter and a transmission gate that are sequentially connected in series between the first latch unit 604 and the inverting drive unit 606. For example, with reference to FIG. 22 and in comparison with FIG. 20, the tri-state gate 720 is replaced with a combination of an inverter 740 and a transmission gate 750, and the combination serves as the second latch unit 605 (specifically, an inverting latch unit) of the dynamic D flip-flop 600. The inverter 740 includes a PMOS transistor 741 and an NMOS transistor 742 that are sequentially connected in series between the power supply VDD and the ground VSS. The transmission gate 750 includes an NMOS transistor 751 and a PMOS transistor 752 that are connected in parallel between the inverter 740 and the inverter 760. The inverter 740 may provide a driving capability for the transmission gate 750. Time sequence control in FIG. 22 is similar to that in FIG. 20, and details are not described herein again.

In some other embodiments, the second latch unit 605 may include the latch circuit according to any one of embodiments of the present disclosure. In such embodiments, the first latch unit 604 may include, for example, one of the following: a transmission gate; a tri-state gate; or an inverter and a transmission gate that are sequentially connected in series between the data input end 601 and the second latch unit 605.

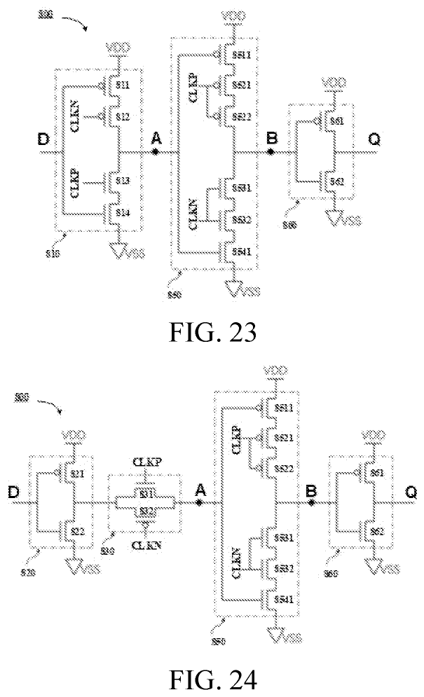

For example, FIG. 23 shows a circuit 800 of the dynamic D flip-flop 600 according to some embodiments of the present disclosure. As shown in FIG. 23, the circuit 800 includes a tri-state gate 810 (which serves as the first latch unit 604 (specifically, an inverting latch unit) of the dynamic D flip-flop 600), a latch circuit 850 (which serves as the second latch unit 605 (specifically, an inverting latch unit) of the dynamic D flip-flop 600), and an inverter 860 (which serves as the inverting drive unit 606 of the dynamic D flip-flop 600) that are sequentially connected in series between a data input end D and a data output end Q. The tri-state gate 810 includes a PMOS transistor 811, a PMOS transistor 812, an NMOS transistor 813, and an NMOS transistor 814 that are sequentially connected in series between a power supply VDD and ground VSS. The latch circuit 850 includes a PMOS transistor 8511, a PMOS transistor 8521, a PMOS transistor 8522, an NMOS transistor 8531, an NMOS transistor 8532, and an NMOS transistor 8541 arranged as in the example shown in FIG. 7, which does not mean any limitation. The inverter 860 includes a PMOS transistor 861 and an NMOS transistor 862 that are sequentially connected in series between a power supply VDD and ground VSS. Time sequence control in FIG. 23 is similar to that in FIG. 20, and details are not described herein again.

In comparison with FIG. 23, in FIG. 24, the tri-state gate 810 is replaced with a combination of an inverter 820 and a transmission gate 830, and the combination serves as the first latch unit 604 (specifically, an inverting latch unit) of the dynamic D flip-flop 600. The inverter 820 includes a PMOS transistor 821 and an NMOS transistor 822 that are sequentially connected in series between a power supply VDD and ground VSS. The transmission gate 830 includes an NMOS transistor 831 and a PMOS transistor 832 that are connected in parallel between the inverter 820 and the latch circuit 850. Time sequence control in FIG. 24 is similar to that in FIG. 20, and details are not described herein again.

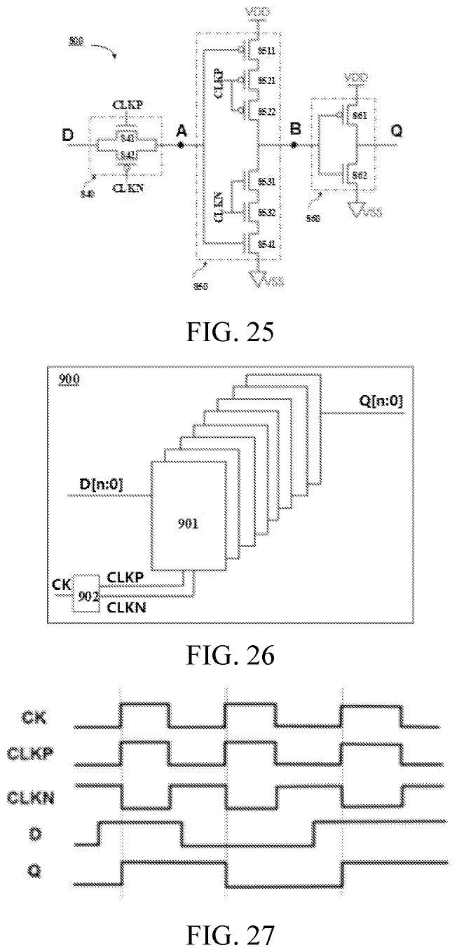

In comparison with FIG. 24, in FIG. 25, the combination of the inverter 820 and the transmission gate 830 is replaced with a transmission gate 840, and the transmission gate 840 serves as the first latch unit 604 (specifically, a non-inverting latch unit) of the dynamic D flip-flop 600. The transmission gate 840 includes an NMOS transistor 841 and a PMOS transistor 842 that are connected in parallel between the data input end D and the latch circuit 850. Time sequence control in FIG. 25 is similar to that in FIG. 20, and details are not described herein again.

In another aspect, the present disclosure provides a register. As shown in FIG. 26, the register 900 includes: a plurality of data input ends D[n:0] configured to receive data signals; a plurality of data output ends Q[n:0] configured to output the data signals; and a clock control end CK configured to receive a clock signal. The register 900 further includes a clock buffer 902 configured to buffer the clock signal received by the clock control end CK and provide the clock signal (CLKP and CLKN) to a plurality of register units 901. The clock buffer 902 is similar to the foregoing clock buffer 200, and details are not described herein again. The register 900 further includes the plurality of register units 901 that are connected in parallel between the plurality of data input ends D[n:0] and the plurality of data output ends Q[n:0], and are configured to write and/or read data under control of the clock signal. In particular, a register unit of the plurality of register units 901 may be the dynamic latch according to any one of embodiments of the present disclosure, or the dynamic D flip-flop according to any one of embodiments of the present disclosure.

Generally, an independent latch or D flip-flop needs a clock buffer to generate clock signals that are inverted with respect to each other for implementing time sequence control. If an independent clock buffer is provided for each latch or D flip-flop, the clock buffers consume a large chip area and considerable power in an application in which a plurality of latches or D flip-flops are need. Therefore, the register according to embodiments of the present disclosure uses one clock buffer to simultaneously drive a plurality of dynamic latches or dynamic D flip-flops. This can effectively reduce an area and power consumption.

In another aspect, the present disclosure provides a processor. The processor includes: the dynamic latch according to any one of embodiments of the present disclosure; or the dynamic D flip-flop according to any one of embodiments of the present disclosure; or the register according to any one of embodiments of the present disclosure.

In another aspect, the present disclosure provides a computing apparatus. The computing apparatus includes the processor according to any one of embodiments of the present disclosure. For example, such a computing apparatus may include, but is not limited to, a computing chip used in fields such as exploration, climate change, transportation, and artificial intelligence, or an electronic device including such a computing chip.

The words “left”, “right”, “front”, “rear”, “top”, “bottom”, “above”, “under”, “upper”, “lower” and the like in the description and the claims, if present, are used for a descriptive purpose and are not necessarily used for describing unchanged relative positions. It should be understood that the words used in such a way are interchangeable in proper circumstances so that the embodiments of the present disclosure described herein, for example, can be operated in other orientations that are different from those shown herein or those described otherwise. For example, when the apparatus in the figure is reversed, the feature originally described as being “above” another feature may now be described as being “below” the other feature. The apparatus may also be oriented in other ways (rotated 90 degrees or in other orientations), and the relative spatial relationship will be explained correspondingly.

In the description and claims, when an element is referred to as being “above”, “attached” to, “connected” to, “coupled” to, or “in contact” with another element, the element may be directly above, directly attached to, directly connected to, directly coupled to, or directly in contact with the other element, or there may be one or more intermediate elements. By contrast, when an element is referred to as “directly above”, “directly attached” to, “directly connected” to, “directly coupled” to, or “directly in contact” with another element, there will be no intermediate element. In the description and claims, a feature being arranged “adjacent” to another feature may refer to the feature having a portion that overlaps with the adjacent feature or a portion located above or below the adjacent feature.

For example, as used herein, the word “illustrative” means “used as an example, instance, or illustration”, and is not intended to be a “model” to be accurately copied. Any implementation illustratively described herein is not necessarily to be construed as preferred or advantageous over other implementations. In addition, the present disclosure is not limited by any stated or implied theory provided in the technical field, background, summary or detailed description.

As used herein, the word “substantially” means that any minor variation caused by the defect of the design or manufacture, the tolerance of the device or the element, the environmental impact, and/or other factors is included. The word “substantially” also allows for the difference from the perfect or ideal situation caused by the parasitic effect, noise, and other practical considerations that may exist in the actual implementation.

Furthermore, terms like “first” and “second” and so on may also be used herein for a reference purpose only, and thus are not intended for a limitation. For example, the terms “first” “second” and other such numerical terms relating to the structure or element do not imply the sequence or the order unless the context clearly indicates otherwise.

It should be further understood that the word “include/comprise”, when used herein, specifies the presence of stated features, integers, steps, operations, units, and/or components, but do not preclude the presence or addition of one or more other features, integers, steps, operations, units, and/or components, and/or combinations thereof. In the present disclosure, the term “provide” is used broadly for covering all manners of obtaining the object, therefore “provide an object” includes, but not limited to, “purchase”, “prepare/manufacture”, “arrange/set”, “install/assemble”, and/or “order”the object.

As used herein, the term “and/or” includes any and all combinations of one or more of the listed items associated with it. The terms used herein are only for the purpose of describing specific embodiments and are not intended to limit the present disclosure. As used herein, the singular forms “a” , “an”, and “the” are also intended to include the plural form, unless the context clearly indicates otherwise.

The same or similar parts between the various embodiments of the present disclosure may be referred to for each other, and each embodiment focuses on the differences from other embodiments. In the description of the present disclosure, the description of the reference terms “one embodiment”, “some embodiments”, “example”, “specific example”, or “some examples”, “for example”, etc. means that the specific features, structures, materials or characteristics described in conjunction with the embodiment or example are included in at least one embodiment or example of the present disclosure. In the present disclosure, the schematic representation of the above terms is not necessarily directed to the same embodiment or example. Moreover, the specific features, structures, materials or characteristics described may be combined in any one or more embodiments or examples in a suitable manner. In addition, those skilled in the art can combine and merge the different embodiments or examples described in the present disclosure and the features of the different embodiments or examples without contradiction.

In addition, when used in the present disclosure, the words “here”, “above”, “below”, “herein”, “hereafter”, “foregoing” and words of similar meaning shall refer to the present disclosure as a whole rather than to any particular portion of the present disclosure. Furthermore, unless expressly stated otherwise or understood otherwise in the context of use, conditional language used herein, such as “may,” “might,” “for example,” “such as,” and the like, is generally intended to express that some embodiments include, while other embodiments do not include, some features, elements, and/or states. Thus, such conditional language is generally not intended to imply that one or more embodiments require features, elements, and/or states in any way, or whether these features, elements, and/or states are included, or whether these features, elements, and/or states are performed in any particular embodiment.

A person skilled in the art should be aware that the boundaries between the foregoing operations are merely illustrative. Multiple operations may be combined into a single operation, a single operation may be distributed in an additional operation, and the operations may be performed at least partially overlapping in time. In addition, alternative embodiments may include a plurality of instances of a particular operation, and the operation order may be changed in other various embodiments. However, other modifications, changes, and replacements are also possible. Aspects and elements of all the embodiments disclosed above may be combined in any way and/or in combination with aspects or elements of other embodiments to provide multiple additional embodiments. Therefore, the description and accompanying drawings are to be regarded as illustrative rather than restrictive.

Although some specific embodiments of the present disclosure have been described in detail through examples, those skilled in the art should understand that the foregoing examples are only for description, but not for limiting the scope of the present disclosure. The embodiments disclosed herein may be arbitrarily combined without departing from the spirit and scope of the present disclosure. Those skilled in the art should also understand that various modifications may be made to the embodiments without departing from the scope and spirit of the present disclosure. The scope of the present disclosure is defined by the attached claims.

1. A latch circuit, comprising:
an input end;
an output end; and
a first transistor group of a first conduction type, a second transistor group of the first conduction type, a third transistor group of a second conduction type different from the first conduction type, and a fourth transistor group of the second conduction type that are sequentially connected in series between a power supply and ground, wherein a node between the second transistor group and the third transistor group is connected to the output end, a control end of one of the first transistor group and the second transistor group and a control end of one of the third transistor group and the fourth transistor group are jointly connected to the input end, a control end of the other of the first transistor group and the second transistor group is configured to receive a first clock signal, and a control end of the other of the third transistor group and the fourth transistor group is configured to receive a second clock signal that is inverted with respect to the first clock signal,
wherein the first conduction type is configured such that a transistor is turned on when a control end of the transistor is at a low level, and the second conduction type is configured such that a transistor is turned on when a control end of the transistor is at a high level, and
wherein at least one of the first to fourth transistor groups comprises a plurality of transistors connected in series.

2. The latch circuit according to claim 1, wherein the control end of the first transistor group and the control end of the fourth transistor group are jointly connected to the input end, the control end of the second transistor group is configured to receive the first clock signal, and the control end of the third transistor group is configured to receive the second clock signal.

3. The latch circuit according to claim 2, wherein at least one of the second transistor group or the third transistor group comprises a plurality of transistors connected in series.

4. The latch circuit according to claim 3, wherein at least one of the first transistor group or the fourth transistor group comprises a plurality of transistors connected in series.

5. The latch circuit according to claim 1, wherein the control end of the second transistor group and the control end of the third transistor group are jointly connected to the input end, the control end of the first transistor group is configured to receive the first clock signal, and the control end of the fourth transistor group is configured to receive the second clock signal.

6. The latch circuit according to claim 5, wherein at least one of the first transistor group or the fourth transistor group comprises a plurality of transistors connected in series.

7. The latch circuit according to claim 6, wherein at least one of the second transistor group or the third transistor group comprises a plurality of transistors connected in series.

8. The latch circuit according to claim 1, wherein a number of transistors in each of the at least one of the first to fourth transistor groups is two.

9. The latch circuit according to claim 1, wherein
a total number of transistors in the first transistor group and the second transistor group is greater than a total number of transistors in the third transistor group and the fourth transistor group, or
a number of transistors in the other of the first transistor group and the second transistor group is greater than a number of transistors in the other of the third transistor group and the fourth transistor group.

10. The latch circuit according to claim 1, wherein
a total number of transistors in the first transistor group and the second transistor group is less than a total number of transistors in the third transistor group and the fourth transistor group, or
a number of transistors in the other of the first transistor group and the second transistor group is less than a number of transistors in the other of the third transistor group and the fourth transistor group.

11. The latch circuit according to claim 1, wherein
a total number of transistors in the first transistor group and the second transistor group is equal to a total number of transistors in the third transistor group and the fourth transistor group, or
a number of transistors in the other of the first transistor group and the second transistor group is equal to a number of transistors in the other of the third transistor group and the fourth transistor group.

12. The latch circuit according to claim 1, wherein transistors in the latch circuit are metal-oxide-semiconductor (MOS) transistors, the first conduction type is P-type, and the second conduction type is N-type.

13. A dynamic latch, comprising:
a data input end configured to receive a data signal;
a data output end configured to output the data signal;
a clock control end configured to receive a clock signal; and
a latch unit and an inverting drive unit that are sequentially connected in series between the data input end and the data output end, wherein the latch unit is configured to latch or transmit the data signal from the data input end under control of the clock signal, and the inverting drive unit is configured to invert and transmit the data signal from the latch unit, and
wherein the latch unit comprises the latch circuit according to claim 1.

14. A dynamic D flip-flop, comprising:
a data input end configured to receive a data signal;
a data output end configured to output the data signal;
a clock control end configured to receive a clock signal; and
a first latch unit, a second latch unit, and an inverting drive unit that are sequentially connected in series between the data input end and the data output end, wherein the first latch unit is configured to latch or transmit the data signal from the data input end under control of the clock signal, the second latch unit is configured to latch or transmit the data signal from the first latch unit under control of the clock signal, and the inverting drive unit is configured to invert and transmit the data signal from the second latch unit, and
wherein the first latch unit comprises the latch circuit according to claim 1.

15. The dynamic D flip-flop according to claim 14, wherein the second latch unit comprises one of:
a tri-state gate, or
the latch circuit according to claim 1, or
an inverter and a transmission gate that are sequentially connected in series between the first latch unit and the inverting drive unit.

16. A dynamic D flip-flop, comprising:
a data input end configured to receive a data signal;
a data output end configured to output the data signal;
a clock control end configured to receive a clock signal; and
a first latch unit, a second latch unit, and an inverting drive unit that are sequentially connected in series between the data input end and the data output end, wherein the first latch unit is configured to latch or transmit the data signal from the data input end under control of the clock signal, the second latch unit is configured to latch or transmit the data signal from the first latch unit under control of the clock signal, and the inverting drive unit is configured to invert and transmit the data signal from the second latch unit, and
wherein the second latch unit comprises the latch circuit according to claim 1.

17. The dynamic D flip-flop according to claim 16, wherein the first latch unit comprises one of:
a transmission gate, or
a tri-state gate, or
an inverter and a transmission gate that are sequentially connected in series between the data input end and the second latch unit.

18. A register, comprising:
a plurality of data input ends configured to receive data signals;
a plurality of data output ends configured to output the data signals;
a clock control end configured to receive a clock signal;
a clock buffer configured to buffer the clock signal received by the clock control end and provide the clock signal to a plurality of register units; and
the plurality of register units that are connected in parallel between the plurality of data input ends and the plurality of data output ends and are configured to perform at least one of data writing or data reading under control of the clock signal,
wherein the register unit of the plurality of register units is the dynamic latch according to claim 13.

19. A processor comprising the dynamic latch according to claim 13.

20. A computing apparatus comprising the processor according of claim 19.
